(19) United States
(12) Patent Application Publication
(10) Pub. No.: US 2021/0335645 A1
(43) Pub. Date: Oct. 28, 2021

(54) SUBSTRATE SUPPORT ASSEMBLY, SUBSTRATE PROCESSING APPARATUS, AND SUBSTRATE PROCESSING METHOD

(71) Applicant: Tokyo Electron Limited, Tokyo (JP)

(72) Inventor: Takehiro UEDA, Miyagi (JP)

(21) Appl. No.: 17/301,899

(22) Filed: Apr. 19, 2021

(30) Foreign Application Priority Data
Apr. 28, 2020 (JP) 2020-079686
Aug. 31, 2020 (JP) 2020-146196

(51) Int. Cl. H01L 21/683; H01J 37/32; H01L 21/67

(52) U.S. Cl. CPC H01L 21/6833; H01L 21/67069; H01J 37/32642

(57) ABSTRACT

A substrate support assembly on which a substrate is placed, includes a base, an electrostatic chuck disposed on the base, and an edge ring disposed in a periphery of the substrate. The edge ring is formed of a plurality of edge ring pieces that are segmented in a circumferential direction. The electrostatic chuck includes a substrate attraction part configured to attract the substrate, and an edge ring attraction part configured to attract the plurality of edge ring pieces. The edge ring attraction part includes a plurality of heat transfer gas grooves, supplied with a heat transfer gas, in a plurality of regions where the plurality of edge ring pieces are attracted, respectively.

### CROSS-REFERENCE TO RELATED APPLICATIONS

This application is based upon and claims priority to Japanese Patent Application No. 2020-079686, filed on Apr. 28, 2020, and Japanese Patent Application No. 2020-146196, filed on Aug. 31, 2020, the entire contents of which are incorporated herein by reference.

### BACKGROUND

### 1. Field of the Invention

The present disclosure relates to substrate support assemblies, substrate processing apparatuses, and substrate processing methods.

### 2. Description of the Related Art

For example, Japanese Laid-Open Patent Publication No. 2015-062237 proposes a substrate processing apparatus including a substrate holder which holds a back surface of a focus ring (edge ring) on a focus ring placing surface by electrostatic attraction, and a heat transfer gas supply which supplies a heat transfer gas to the back surface of the focus ring.

### SUMMARY

According to one aspect of the present disclosure, there is provided a substrate support assembly on which a substrate is placed, including a base; an electrostatic chuck disposed on the base; and an edge ring disposed in a periphery of the substrate, wherein the edge ring is formed of a plurality of edge ring pieces that are segmented in in a circumferential direction, wherein the electrostatic chuck includes a substrate attraction part configured to attract the substrate, and an edge ring attraction part configured to attract the plurality of edge ring pieces, and wherein the edge ring attraction part includes a plurality of heat transfer gas grooves, supplied with a heat transfer gas, in a plurality of regions where the plurality of edge ring pieces are attracted, respectively.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIG. 1 is a cross sectional view illustrating a general configuration of a substrate processing apparatus according to one embodiment.

FIG. 2 is an enlarged cross sectional view of a periphery of an edge ring of the substrate processing apparatus according to one embodiment.

FIG. 3 is a top view of a substrate support assembly of the substrate processing apparatus according to one embodiment.

FIG. 4 is a top view of an electrostatic chuck of the substrate processing apparatus according to one embodiment.

FIG. 5 is a cross sectional view of the electrostatic chuck of the substrate processing apparatus according to one embodiment.

FIG. 6 is a diagram for explaining a supply of a heat transfer gas to the electrostatic chuck of the substrate processing apparatus according to one embodiment.

FIG. 7 is a diagram for explaining a pressure control of the heat transfer gas to the electrostatic chuck of the substrate processing apparatus according to one embodiment.

FIG. 8A and FIG. 8B are diagrams for explaining a correlation between an edge ring temperature and a pressure setting value of the substrate processing apparatus according to one embodiment.

FIG. 9 is a diagram for explaining an example of an etching rate distribution of the substrate processing apparatus according to one embodiment.

FIG. 10 is a diagram for explaining a relationship between a pressure of the heat transfer gas on a back surface of a wafer and a wafer temperature.

FIG. 11 is a diagram for explaining a substrate processing method of the substrate processing apparatus according to one embodiment.

FIG. 12 is a diagram for explaining a supply of power to the electrostatic chuck of the substrate processing apparatus according to one embodiment.

FIG. 13 is a diagram for explaining the substrate processing method of the substrate processing apparatus according to one embodiment.

FIG. 14 is a diagram for explaining a processing number and an etching rate variation in the substrate processing apparatus according to one embodiment.

FIG. 15 is a cross sectional view of ends of the edge ring of the substrate processing apparatus according to one embodiment.

FIG. 16 is a cross sectional view of the ends of the edge ring of the substrate processing apparatus according to one embodiment.

FIG. 17 is a cross sectional view of the ends of the edge ring of the substrate processing apparatus according to one embodiment.

### DETAILED DESCRIPTION

Embodiments of the present disclosure will be described hereinafter, with reference to the drawings. In the present specification and the drawings, substantially the same constituent elements (that is, components, parts, members, or the like) are designated by the same reference numerals, and a repeated description of the same or corresponding constituent elements will be omitted. For the sake of facilitating the understanding, the scale of the parts in the drawings may differ from the actual scale of the parts. The directions, such as parallel, perpendicular, orthogonal, horizontal, vertical, up and down, and left and right directions or the like, may tolerate a deviation to such an extent that does not deteriorate effects obtainable by the embodiments. The shapes of corners are not limited to right angles, and may be rounded to arcuate shapes. The states, such as parallel, perpendicular, orthogonal, horizontal, and vertical may include approximately parallel, approximately perpendicular, approximately orthogonal, approximately horizontal, and approximately vertical states, respectively.

The present disclosure provides a technique for reducing a leak of a heat transfer gas during an edge ring attraction.

### General Configuration of Substrate Processing Apparatus 1

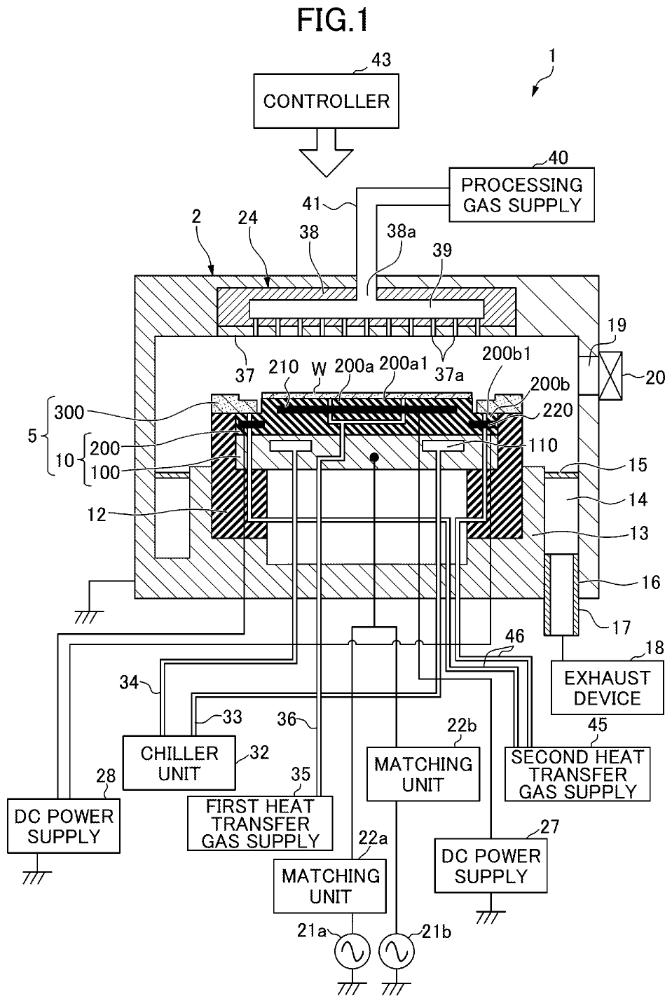

First, an example of a general configuration of a substrate processing apparatus 1 will be described, with reference to FIG. 1. FIG. 1 is a cross sectional view illustrating the general configuration of the substrate processing apparatus 1 according to one embodiment. In an example described in this embodiment, the substrate processing apparatus 1 is a Reactive Ion Etching (RIE) type substrate processing apparatus. However, the substrate processing apparatus 1 may be a plasma etching apparatus, a plasma Chemical Vapor Deposition (CVD) apparatus, or the like.

In FIG. 1, the substrate processing apparatus 1 includes a cylindrical processing chamber 2 which is grounded and is made of a metal, such as aluminum, stainless steel, or the like. A disc-shaped substrate support (or stage) 10 on which a substrate W is placed, is disposed inside the processing chamber 2. The substrate support 10 includes a base 100, and an electrostatic chuck 200. The base 100 functions as a lower electrode. The base 100 is made of aluminum, for example. The base 100 is supported on a cylindrical support 13 extending vertically upward from a bottom of the processing chamber 2, via an insulating cylindrical holding member 12.

An exhaust passage 14 is formed between a sidewall of the processing chamber 2 and the cylindrical support 13. An annular baffle plate 15 is disposed at an inlet or an intermediate portion of the exhaust passage 14. An exhaust port 16 is provided at the bottom of the processing chamber 2. An exhaust device 18 is connected to the exhaust port 16 via an exhaust pipe 17. The exhaust device 18 includes a dry pump, and a vacuum pump, and is configured to reduce a pressure of a processing space inside the processing chamber 2 to a predetermined vacuum level. In addition, the exhaust pipe 17 includes an Automatic Pressure Control (APC) valve, which is a variable butterfly valve, and the APC valve automatically controls the pressure inside the processing chamber 2. Further, a gate valve 20, which opens and closes a gate 19 through which the substrate W is transported into and out from the processing chamber 2, is mounted on the sidewall of the processing chamber 2.

The base 100 is connected to a Radio Frequency (RF) power supply via a matching unit. In the example illustrated in FIG. 1, the base 100 is connected to a first RF power supply 21a via a matching unit 22a. In addition, the base 100 is connected to a second RF power supply 21b via a matching unit 22b. The first RF power supply 21a supplies RF power, having a first predetermined frequency (for example, 40 MHz) for plasma generation, to the base 100. The second RF power supply 21b supplies RF power, having a second predetermined frequency (for example, 400 kHz) for ion attraction, to the base 100. The second predetermined frequency of the RF power supplied from the second RF power supply 21b is lower than the first predetermined frequency of the RF power supplied from the first RF power supply 21a.

A shower head 24, which also functions as an upper electrode, is disposed on a ceiling of the processing chamber 2. Hence, the RF power having the first predetermined frequency from the first RF power supply 21a, and the RF power having the second predetermined frequency from the second RF power supply 21b, are supplied between the base 100 and the shower head 24.

The electrostatic chuck 200, which attracts the substrate W by an electrostatic attraction force, is provided on an upper surface of the base 100. The electrostatic chuck 200 includes a disc-shaped substrate attraction part 200a on which the substrate W is placed, and an annular edge ring attraction part 200b formed to surround the substrate attraction part 200a. The substrate attraction part 200a protrudes upward in FIG. 1 with respect to the edge ring attraction part 200b. An upper surface of the substrate attraction part 200a is a substrate placing (or setting) surface 200a1 on which the substrate W is placed (or set). An upper surface of the edge ring attraction part 200b is an edge ring placing (or setting) surface 200b1 on which the edge ring 300 is placed (or set). The edge ring placing surface 200b1 is configured to place the edge ring 300 in a periphery of the substrate placing surface 200a1. The edge ring 300 may also be referred to as a focus ring. As will be described later, in the substrate processing apparatus 1 according to this embodiment, the edge ring 300 is famed of a plurality of edge ring pieces 301 through 306.

The substrate attraction part 200a is formed by sandwiching a substrate attraction electrode plate 210 made of a conductive film, between a pair of dielectric films. A DC power supply 27 is electrically connected to the substrate attraction electrode plate 210. The edge ring attraction part 200b is famed by sandwiching an edge ring attraction electrode plate 220 made of a conductive film, between a pair of dielectric films. A DC power supply 28 is electrically connected to the edge ring attraction electrode plate 220. As will be described later, in the substrate processing apparatus 1 according to this embodiment, a plurality of edge ring attraction electrode plates are provided in the edge ring attraction part 200b. A DC power supply 28 is electrically connected to each of the plurality of edge ring attraction electrode plates. In the present disclosure, when the respective electrode plates of the edge ring attraction part 200b do not need to be particularly distinguished from one another, these electrode plates are collectively referred to as edge ring attraction electrode plates 220.

A combination of the substrate support 10 and the edge ring 300 may be referred to as a substrate support assembly 5.

Each of the DC power supply 27 and the DC power supply 28 has a configuration capable of changing the level and polarity of the DC voltage supplied thereby. The DC power supply 27 applies a DC voltage to the substrate attraction electrode plate 210 under a control of a controller 43 which will be described later. The DC power supply 28 applies a DC voltage to the edge ring attraction electrode plate 220 under the control of the controller 43. The electrostatic chuck 200 generates an electrostatic force, such as a Coulomb force or the like, in response to the DC voltage applied from the DC power supply 27 to the substrate attraction electrode plate 210, and attracts and holds the substrate W onto the electrostatic chuck 200 by the electrostatic force. In addition, the electrostatic chuck 200 generates an electrostatic force, such as a Coulomb force or the like, in response to the DC voltage applied from the DC power supply 28 to the edge ring attraction electrode plate 220, and attracts and holds the edge ring 300 onto the electrostatic chuck 200 by the electrostatic force. The DC power supply 28 may apply individual voltages to each of the plurality of edge ring attraction electrode plates 220.

The electrostatic chuck 200 according to this embodiment integrally includes the substrate attraction part 200a and the edge ring attraction part 200b. However, the substrate attraction part 200a and the edge ring attraction part 200b may be included in separate electrostatic chucks. In other words, the pair of dielectric films sandwiching the substrate attraction electrode plate 210, and the pair of dielectric films sandwiching the edge ring attraction electrode plate 220, may be independent of each other. Moreover, the edge ring attraction electrode plate 220 in this embodiment is illustrated as an example of a monopolar electrode, but may be a bipolar electrode. In the case of the bipolar electrode, the electrostatic chuck 200 can attract the edge ring 300 even when no plasma is generated.

A flow passage 110, which extends in a circumferential direction, for example, is provided inside the base 100. A coolant having a predetermined temperature, such as cooling water, for example, is circulated and supplied to the flow passage 110 from a chiller unit 32, via pipes 33 and 34, thereby controlling a processing temperature of the substrate W on the electrostatic chuck 200 and a temperature of the edge ring 300, according to the temperature of the coolant. The coolant is an example of a temperature adjusting medium (or temperature controlling medium) that is circulated and supplied to the flow passage 110. The temperature control medium may be used to not only cool the base 100 and the substrate W, but may also be used to heat the base 100 and the substrate W.

The first heat transfer gas supply 35 is connected to the electrostatic chuck 200 via a gas supply line 36. The first heat transfer gas supply 35 uses the gas supply line 36 to supply the heat transfer gas to a space sandwiched between the substrate attraction part 200a of the electrostatic chuck 200 and the substrate W. A second heat transfer gas supply 45 is connected to the electrostatic chuck 200 via a gas supply line 46. The second heat transfer gas supply 45 uses the gas supply line 46 to supply the heat transfer gas to a space sandwiched between the edge ring attraction part 200b of the electrostatic chuck 200 and the edge ring 300. A gas having heat conductivity, such as He gas, or the like, for example, is preferably used as the heat transfer gas. The heat transfer gas is supplied from the second heat transfer gas supply 45 in correspondence with each of a plurality of edge rings.

By supplying the heat transfer gas between the electrostatic chuck 200 and the substrate W, and between the electrostatic chuck 200 and the edge ring 300, the heat of the plasma input to the substrate W or the edge ring 300, can be transferred efficiently to the base 100.

The shower head 24, which is disposed on the ceiling, includes an electrode plate 37, and an electrode support 38 configured to detachably support the electrode plate 37. The electrode plate 37 is provided on a lower surface of the shower head 24, and includes a plurality of gas vent holes 37a. A buffer chamber 39 is provided inside the electrode support 38, and a processing gas supply 40 is connected to a gas inlet 38a which communicates to the buffer chamber 39, via a gas supply line 41.

Each constituent element of the substrate processing apparatus 1 may be connected to the controller 43. For example, the exhaust device 18, the first RF power supply 21a, the second RF power supply 21b, the matching unit 22a, the matching unit 22b, the DC power supply 27, the DC power supply 28, the chiller unit 32, the first heat transfer gas supply 35, the second heat transfer gas supply 45, and the processing gas supply 40 are connected to the controller 43. The controller 43 can control each constituent element of the substrate processing apparatus 1.

The controller 43 includes a Central Processing Unit (CPU), and a storage device, such as a memory or the like, which are not illustrated in FIG. 1. The CPU of the controller 43 reads out a program and a processing recipe stored in the storage device, and executes the program and the processing recipe, thereby performing a desired process in the substrate processing apparatus 1 by reading out and executing a program and a processing recipe stored in the storage device. In addition, the controller 43 performs an electrostatic attraction process to electrostatically attract the edge ring 300.

First, in the substrate processing apparatus 1, the gate valve 20 is opened and the substrate W to be processed (that is, a processing target) is transported into the processing chamber 2 and placed on the electrostatic chuck 200. Then, in the substrate processing apparatus 1, the processing gas supply 40 supplies a processing gas (for example, a gas mixture of C₄F₈ gas, O₂ gas, and Ar gas) into the processing chamber 2 at predetermined flow rate and flow rate ratio, and the pressure inside the processing chamber 2 is set to a predetermined value by the exhaust device 18 or the like.

Further, in the substrate processing apparatus 1, the first RF power supply 21a and the second RF power supply 21b supply the RF powers having different frequencies to the base 100. Moreover, in the substrate processing apparatus 1, the DC power supply 27 applies the DC voltage to the substrate attraction electrode plate 210 of the electrostatic chuck 200, so that the substrate W is attracted onto the electrostatic chuck 200. In the substrate processing apparatus 1, the DC power supply 28 applies the DC voltage to the edge ring attraction electrode plate 220 of the electrostatic chuck 200, so that the edge ring 300 is attracted onto the electrostatic chuck 200. The processing gas discharged from the shower head 24 is plasmatized, and the substrate W is subjected to an etching process by radicals and ions in the plasma.

### Attraction of Edge Ring 300

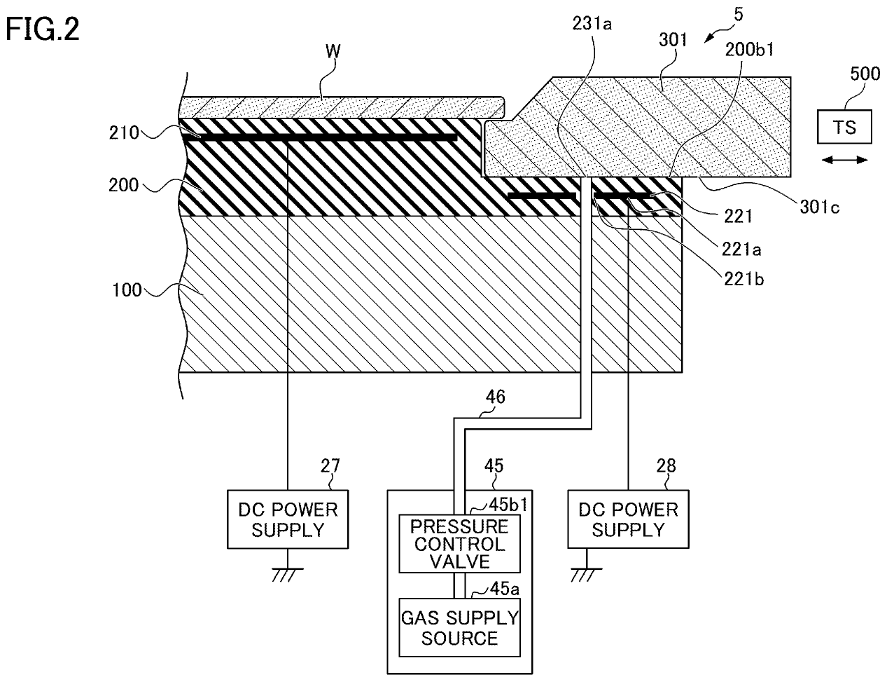

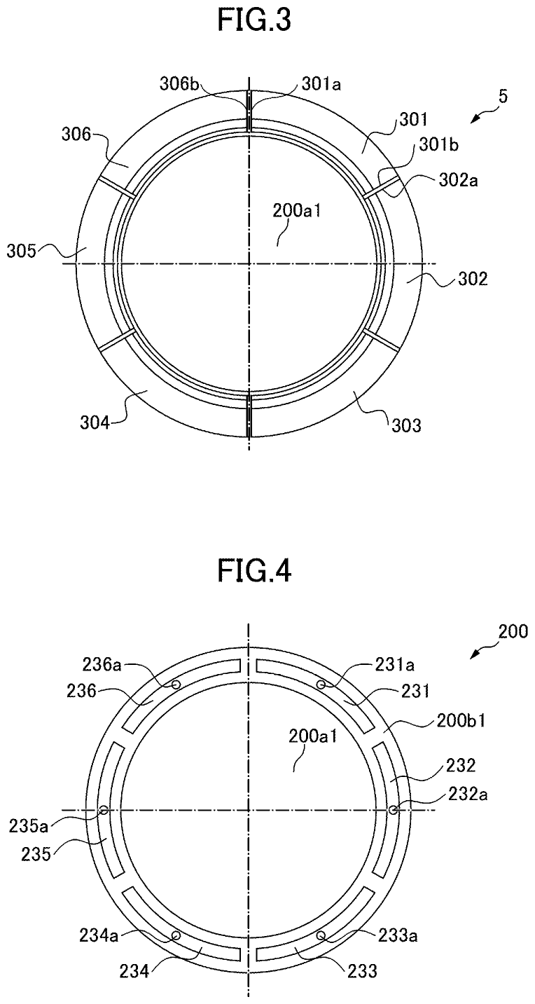

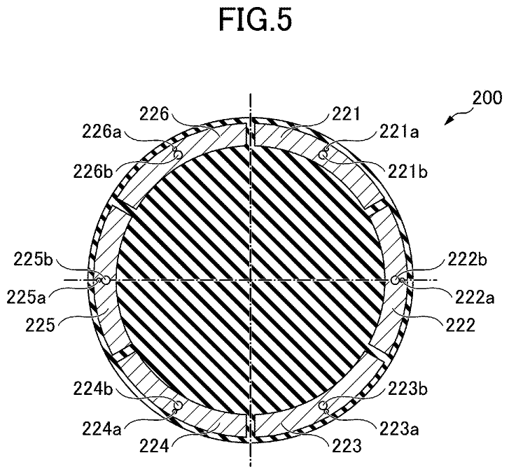

The attraction of the edge ring 300 will be described. FIG. 2 is an enlarged cross sectional view illustrating a periphery of the edge ring 300 of the substrate processing apparatus 1 according to this embodiment. In the substrate processing apparatus 1 according to this embodiment, the edge ring 300 includes a plurality of edge ring pieces 301 through 306 that are segmented in a circumferential direction. In addition, the substrate processing apparatus 1 includes edge ring attraction electrode plates 221 through 226 in correspondence with the edge ring pieces 301 through 306, respectively, as illustrated in FIG. 3 and FIG. 5. A description will be given of the edge ring piece 301 and the edge ring attraction electrode plate 221, as an example of one of the edge ring pieces 301 through 306, and an example of the corresponding one of the edge ring attraction electrode plates 221 through 226.

The edge ring piece 301 is attracted onto the electrostatic chuck 200 by the edge ring attraction electrode plate 221. The edge ring attraction electrode plate 221 includes a power feed part 221a which is supplied with the voltage from the DC power supply 28. In addition, the edge ring attraction electrode plate 221 includes a through hole 221b penetrated by the gas supply line 46.

The edge ring placing surface 200b1 of the electrostatic chuck 200 includes a heat transfer gas supply hole 231a, and the heat transfer gas from the gas supply line 46 is supplied to the heat transfer gas supply hole 231a.

The heat transfer gas is supplied from the second heat transfer gas supply 45 to the heat transfer gas supply hole 231a via the gas supply line 46. The second heat transfer gas supply 45 includes a gas supply source 45a, and a pressure control valve 45b1. As will be described later, the second heat transfer gas supply 45 includes pressure control valves 45b1 through 45b6 in correspondence with the plurality of edge ring pieces 301 through 306, respectively. In FIG. 2, one edge ring piece 301 will be described.

The heat transfer gas supplied to the heat transfer gas supply hole 231a is supplied between a back surface 301c of the edge ring piece 301 and the edge ring placing surface 200b1, via a heat transfer gas groove 231 (refer to FIG. 4) provided in the edge ring placing surface 200b1.

The processing chamber 2 is an example of a processing chamber.

### Edge Ring 300 of Substrate Processing Apparatus 1

FIG. 3 is a top view of the substrate support assembly 5 of the substrate processing apparatus 1 according to this embodiment. The substrate support assembly 5 includes a plurality of edge rings 300 which are placed on and attracted onto the edge ring placing surface 200b1 of the electrostatic chuck 200. More particularly, the substrate support assembly 5 includes six edge ring pieces 301 through 306. The edge ring pieces 301 through 306 are disposed in a periphery of the substrate placing surface 200a1, that is, the substrate W. The edge ring pieces 301 through 306 have the same shape. The number of edge ring pieces may be two or more, as long as the entire edge ring placing surface 200b1 can be covered thereby. From a viewpoint of reducing the leak of the heat transfer gas and sufficient workability, the number of edge ring pieces is preferably three to nine, and more preferably four to eight. In addition, the edge ring pieces may have shapes that segment the edge ring placing surface 200b1 in the circumferential direction at unequal intervals.

### Edge Ring Placing Surface 200b1 of Electrostatic Chuck 200

Next, the edge ring placing surface 200b1 of the electrostatic chuck 200 (edge ring attraction part 200b) will be described. FIG. 4 is a top view of the electrostatic chuck 200 of the substrate processing apparatus 1 according to this embodiment. The electrostatic chuck 200 includes heat transfer gas grooves 231 through 236 in the edge ring placing surface 200b1 of the electrostatic chuck 200, in correspondence with the edge ring pieces 301 through 306, respectively. More particularly, the electrostatic chuck 200 includes the heat transfer gas groove 231 in a region of the electrostatic chuck 200 (a portion of the electrostatic chuck 200 opposing the back surface of the edge ring piece 301) where the edge ring piece 301 is attracted. Similarly, the edge ring attraction part 200b includes the heat transfer gas grooves 232, 233, 234, 235, and 236 in portions of the electrostatic chuck 200 opposing the back surfaces of the edge ring pieces 302, 303, 304, 305, and 306, respectively. Each of the heat transfer gas grooves 231 through 236 is formed to cave in in a direction perpendicular to the edge ring placing surface 200b1. The heat transfer gas grooves 231 through 236 include heat transfer gas supply holes 231a through 236a, 236a, respectively. The heat transfer gas supplied from the heat transfer gas supply hole 231a is filled into the space between the edge ring piece 301 and the heat transfer gas groove 231. The same applies to the edge ring pieces 302 through 306 and the heat transfer gas grooves 232 through 236. The heat transfer gas grooves 231 through 236 include the heat transfer gas supply holes 231a through 236a, respectively, and are provided separately from one another, so that the heat transfer gas can be supplied independently to each of the heat transfer gas grooves 231 through 236. The shape of the heat transfer gas groove is not limited to a fan shape, as long as the heat transfer gas grooves communicates with the corresponding heat transfer gas supply hole, and the heat transfer gas groove may be segmented in a radial direction or a circumferential direction.

### Edge Ring Attraction Electrode Plate 220 of Electrostatic Chuck 200

Next, the edge ring attraction electrode plate 220 of the electrostatic chuck 200 will be described. FIG. 5 is a cross sectional view of the electrostatic chuck 200 of the substrate processing apparatus 1 according to this embodiment. More particularly, FIG. 5 illustrates the cross sectional view of a portion of the edge ring attraction electrode plate 220 of the electrostatic chuck 200 cut along a plane parallel to the edge ring placing surface 200b1.

The electrostatic chuck 200 includes the edge ring attraction electrode plates 221 through 226 corresponding to the edge ring pieces 301 through 306, respectively. More particularly, the electrostatic chuck 200 includes the edge ring attraction electrode plate 221 inside a region of the electrostatic chuck 200 (a portion of the electrostatic chuck 200 opposing the back surface of the edge ring piece 301) where the edge ring piece 301 is attracted. Similarly, the electrostatic chuck 200 includes the edge ring attraction electrode plates 222, 223, 224, 225, and 226 inside portions of the electrostatic chuck 200 opposing the back surfaces of the edge ring piece 302, 303, 304, 305, and 306, respectively. The edge ring attraction electrode plates 221 through 226 include power feed parts 221a through 226a supplied with the power from the DC power supply 28, respectively. In addition, the edge ring attraction electrode plates 221 through 226 include through holes 221b through 226b penetrated by the gas supply line 46, respectively. Because the edge ring attraction electrode plates 221 through 226 include power feed parts 221a through 226a, respectively, and are provided separately from one another, a voltage can be supplied (applied) independently to each of the edge ring attraction electrode plates 221 through 226.

The leak of the heat transfer gas can be controlled by controlling the voltages applied to the edge ring attraction electrode plates 221 through 226. By controlling the applied voltages to control (reduce) the leak, the temperatures of the edge ring pieces 301 through 306 can be stabilized.

### Supply of Heat Transfer Gas to Electrostatic Chuck 200

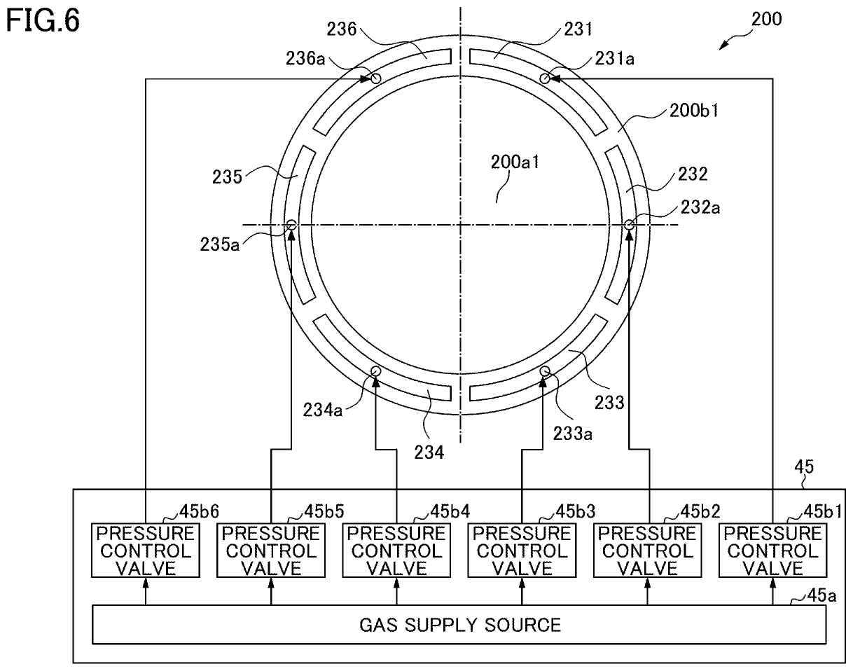

Next, an example of a control method for controlling the substrate support assembly 5 will be described. In this example, the supply of the heat transfer gas to the electrostatic chuck 200 will be described. FIG. 6 is a diagram for explaining the supply of the heat transfer gas to the electrostatic chuck 200 of the substrate processing apparatus 1 according to this embodiment. The heat transfer gas supply holes 231a through 236a of the heat transfer gas grooves 231 through 236, provided in correspondence with the edge ring pieces 301 through 306, are connected to the second heat transfer gas supply 45. The second heat transfer gas supply 45 includes the pressure control valves 45b1 through 45b6 in correspondence with the heat transfer gas grooves 231 through 236, respectively. The pressure of each of the pressure control valves 45b1 through 45b6 can be set by the controller 43. Each of the pressure control valves 45b1 through 45b6 controls the pressure of the heat transfer gas that is supplied to a pressure setting value which is set. The substrate support assembly 5 is controlled by controlling the heat transfer gas to the electrostatic chuck 200.

The controller 43 may set the pressure setting values of the pressure control valves 45b1 through 45b6 to be the same value. In addition, the pressure setting values of the pressure control valves 45b1 through 45b6 may be varied, based on a result of a substrate processing by the substrate processing apparatus 1. For example, the pressure setting value of the pressure control valve corresponding to the edge ring piece located close to a region where a processing rate is fast, may be varied (for example, increased) so that the processing rate becomes slower. Further, the controller 43 may vary the pressure setting values of the pressure control valves 45b1 through 45b6, based on the temperatures of the edge ring pieces 301 through 306, respectively. For example, the pressure setting value of the pressure control valve corresponding to the edge ring piece having a high temperature may be varied (for example, increased).

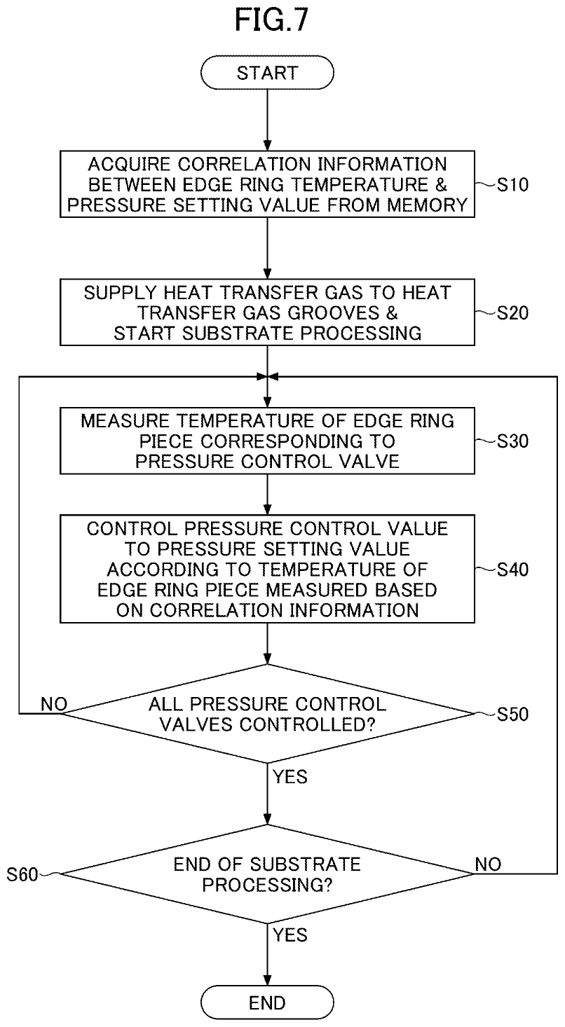

In this example, the control method for varying the pressure setting value of the pressure control valves 45b1 through 45b6, based on the temperatures of the edge ring piece 301 through 306, respectively, will be described. FIG. 7 is a diagram for explaining a pressure control of the heat transfer gas to the electrostatic chuck 200 of the substrate processing apparatus 1 according to this embodiment. More particularly, FIG. 7 is a flow chart of the control carried out by the controller 43. Each processing step (or process) will now be described.

### Step S10

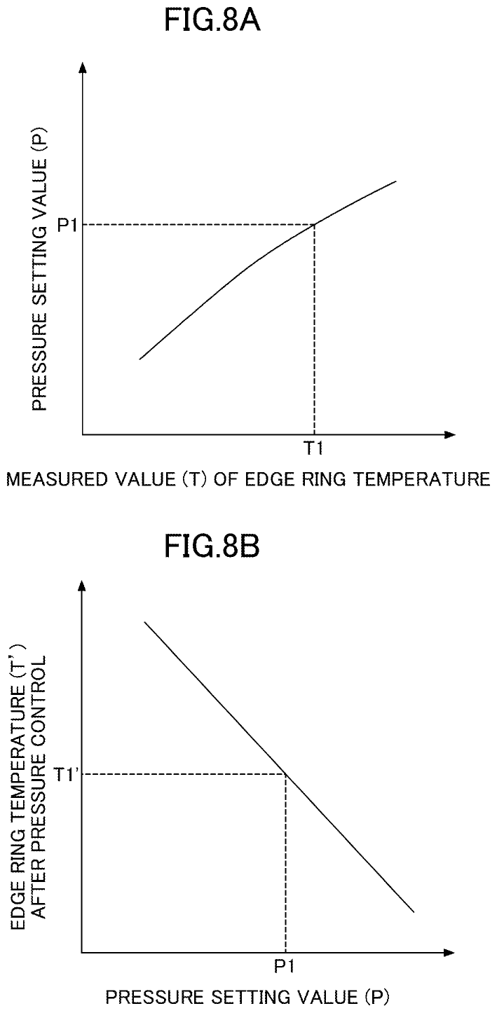

First, the controller 43 acquires, from the memory, correlation information (data indicating a correlation) between the temperatures (edge ring temperatures) of the edge ring pieces and the pressure setting values of the pressure control valve. The memory stores the correlation information (data indicating the correlation) between the edge ring temperatures and the pressure setting values of the pressure control valve, obtained by performing measurements in advance. FIG. 8A and FIG. 8B are diagrams for explaining the correlation between the edge ring temperature of the substrate processing apparatus 1 according to this embodiment, and the pressure setting value of the pressure control valve. FIG. 8A is a diagram illustrating a relationship between an edge ring temperature (T) measured in step S30 which will be described later, and a pressure setting value (P) of the heat transfer gas to be controlled by the pressure control valve. On the other hand, FIG. 8B is a diagram illustrating an edge ring temperature (T′) for a case where the pressure setting value (P) of the heat transfer gas is controlled according to FIG. 8A, assuming that the heat input from the plasma is constant. The memory is an example of the storage device.

A storage location of the correlation information (data indicating the correlation) between the edge ring temperatures and the pressure setting values of the pressure control valve is not limited to the memory. The correlation information may be stored in a device or a medium capable of storing information, such as a disk drive or the like, for example.

### Step S20

Next, the controller 43 supplies the heat transfer gas to the heat transfer gas grooves, and carries out a control so as to start and perform the substrate processing.

### Step S30

Next, the controller 43 carries out a control, so as to measure the temperature of each of the edge ring pieces corresponding to the pressure control valve. For example, the controller 43 carries out the control, so as to measure the temperature of the edge ring piece 301 corresponding to the pressure control valve 45b1. The temperature of each of the edge ring pieces may be measured optically, or may be measured by providing a temperature sensor (TS) 500 illustrated in FIG. 2 and moving the temperature sensor 500 in a direction of an arrow to make contact with each of the edge ring pieces for the temperature measurement. Of course, the location of the temperature sensor 500 is not particularly limited, as long as the temperature sensor 500 can make contact with each of the edge ring pieces for the temperature measurement.

### Step S40

Next, the controller 43 obtains the pressure setting value of the pressure control valve from the temperature of the edge ring piece measured in step S30, such as the temperature of the edge ring piece 301, for example, and the correlation information (data indicating the correlation) acquired in step S10. Further, the controller 43 controls the pressure of the pressure control valve corresponding to the edge ring whose temperature is measured in step S30, such as the pressure of the pressure control valve 45b1 corresponding to the edge ring piece 301, for example, to the pressure setting value obtained as described above.

For example, in a case where the temperature of the edge ring piece 301 measured in step S30 is T1, the pressure control valve 45b1 is controlled based on FIG. 8A to adjust the pressure setting value to P1. As a result, assuming that the heat input from the plasma is constant, it can be seen from FIG. 8B that the temperature of the edge ring piece 301 finally becomes T1′.

### Step S50

Next, the controller 43 determines whether or not all the pressure control valves have been controlled. If there is a pressure control valve which has not been controlled and the decision result in step S50 is No, the process returns to step S20 in order to repeat the process from step S20. For example, if the control of the pressure control valve 45b1 ended and the control of the pressure control valve 45b2 is not yet carried out, the process returns to step S20 in order to control the pressure control valve 45b2. The same applies to the other pressure control valves. If all of the pressure control valves have been controlled and the decision result in step S50 is Yes, the process advances to step S60.

### Step S60

Next, the controller 43 determines whether or not the substrate processing ended. If the substrate processing ended and the decision result in step S60 is Yes, the process ends. If the substrate processing has not yet ended and the decision result in step S60 is No, the process returns to step S30 in order to repeat the process from step S30. The processing of the substrate (substrate processing step) is performed in parallel, between step S20 and step S60.

By performing the process described above, the pressure setting value of the pressure control valve, that is, the pressure supplied to each of the heat transfer gas grooves, is varied based on the temperature of the corresponding edge ring piece, by referring to the storage device which stores the correlation information (data indicating the correlation) between the temperatures of the edge ring pieces and the pressure setting values. The substrate processing method, including the control method described above, is an example of the substrate processing method using the substrate processing apparatus 1.

Although the temperature of the edge ring piece is measured in step S30, the temperature of the edge ring piece may be estimated from the result of the substrate processing. In addition, the temperature during the etching process may be controlled by a feedback control.

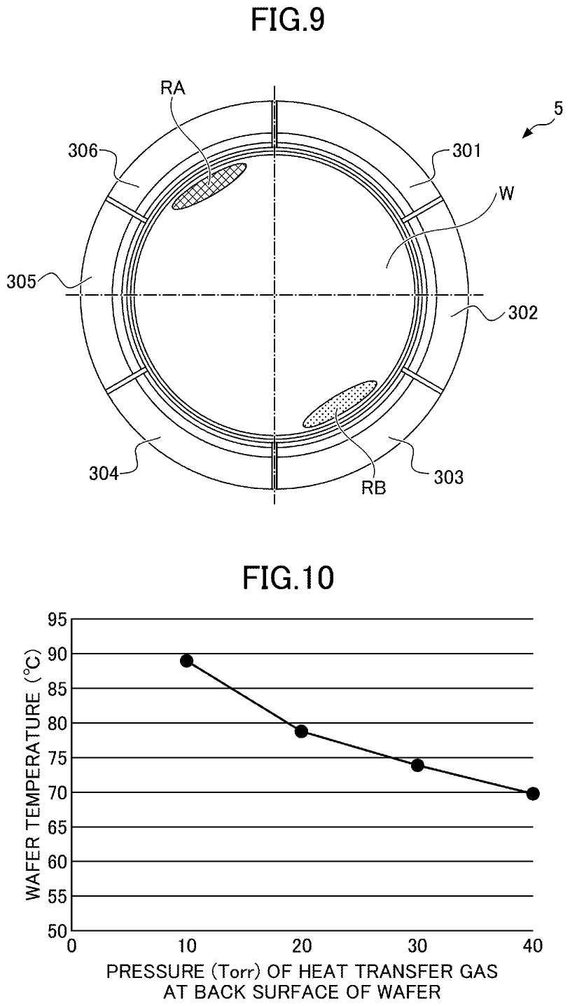

FIG. 9 is a diagram for explaining an example of an etching rate distribution of the substrate processing apparatus 1 according to this embodiment. For example, in FIG. 9, a region RA of the substrate W (wafer) indicates the portion where the etching rate is desirably increased. Further, in FIG. 9, a region RB of the substrate W (wafer) indicates the portion where the etching rate is desirably decreased.

First, the region RA of the substrate W (wafer) will be described. When increasing the etching rate of the region RA of the substrate W (wafer), the pressure of the heat transfer gas at the edge ring piece 306 near the region RA is increased. FIG. 10 is a diagram illustrating a relationship between the pressure of the heat transfer gas on the back surface of the wafer and the temperature of the wafer. As the pressure of the heat transfer gas on the back surface of the wafer becomes higher, the temperature of the wafer becomes lower. Similarly, with respect to the edge ring piece 306, increasing the pressure of the heat transfer gas at the edge ring piece 306 decreases the temperature of the edge ring piece 306. By decreasing the temperature of the edge ring piece 306, it is possible to increase the etching rate in the region RA of the substrate W (wafer) near the edge ring piece 306. The description given above is merely an example, and depending on the type of film (film material) on the substrate W, the etching rate may decrease when the temperature of the edge ring piece is decreased. In this case, by increasing the temperature of the edge ring piece, it is possible to increase the etching rate.

Next, the region RB of the substrate W (wafer) will be described. When decreasing the etching rate of the region RB of the substrate W (wafer), the pressure of the heat transfer gas at the edge ring piece 303 near the region RB is decreased. Similar to FIG. 10, with respect to the edge ring piece 303, the temperature of the edge ring piece 303 increases as the pressure of the heat transfer gas at the edge ring piece 303 is decreased. By increasing the temperature of the edge ring piece 303, it is possible to decrease the etching rate in the region RB of the substrate W (wafer) near the edge ring piece 303. The description given above is merely an example, and depending on the type of film on the substrate W, the etching rate may increase when the temperature of the edge ring piece is increased. In this case, by decreasing the temperature of the edge ring piece, it is possible to decrease the etching rate.

Accordingly, by forming the edge ring 300 from the plurality of edge ring pieces 301 through 306 segmented in the circumferential direction, and independently controlling the pressures of the plurality of edge ring pieces 301 through 306, it is possible to improve the temperature controllability of the edge ring 300. In other words, the temperature control can be performed for each of the regions corresponding to the plurality of edge ring pieces 301 through 306 segmented in the circumferential direction.

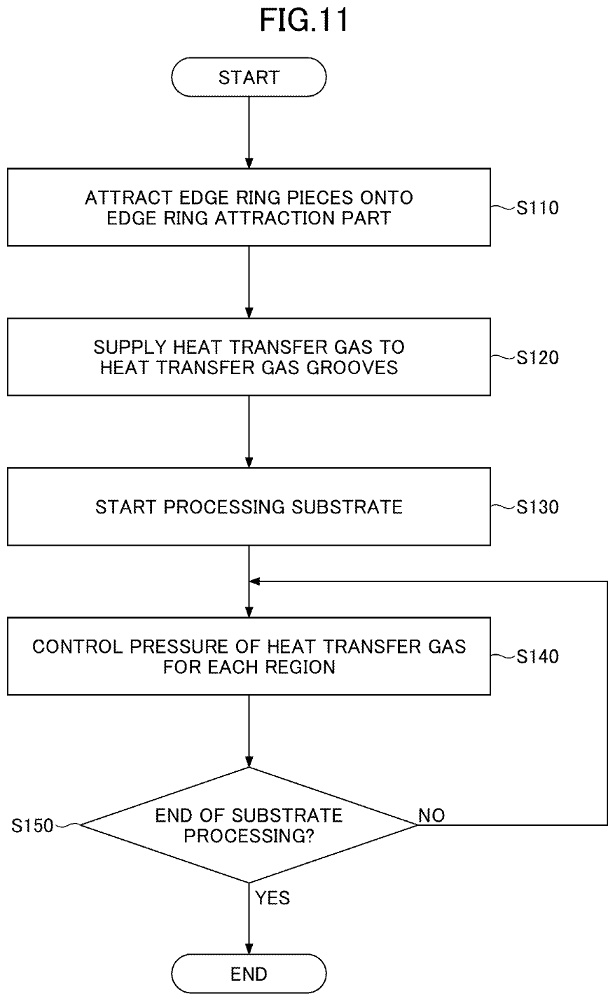

Next, the substrate processing method using the substrate processing apparatus 1 will be described. FIG. 11 is a diagram for explaining the substrate processing method of the substrate processing apparatus 1 according to this embodiment. More particularly, FIG. 11 is a flow chart of the control carried out by the controller 43. Each processing step (process) will now be described.

### Step S110

First, the controller 43 carries out a control so as to attract the plurality of edge ring pieces 301, 302, 303, 304, 305, and 306 onto the edge ring attraction part 200b.

### Step S120

Next, the controller 43 carries out a control supplies the heat transfer gas to the heat transfer gas grooves so as to execute the substrate processing.

### Step S130

Next, the controller 43 starts processing (substrate processing) of the substrate W (wafer). For example, the substrate processing etches the substrate W (wafer).

### Step S140

Next, the controller 43 carries out a control to control the pressure of the heat transfer gas for each of the regions, that is, each of the edge ring pieces.

### Step S150

Next, the controller 43 determines whether or not the substrate processing ended. If the substrate processing ends and the decision result in step S150 is Yes, the process ends. On the other hand, if the substrate processing has not ended and the decision result in step S150 is No, the process returns to step S140 in order to repeat the process from step S140. The processing of the substrate (substrate processing step) is performed in parallel, between step S130 and step S150.

By performing the process described above, it is possible to control the temperature for each of the edge ring pieces.

### Supply to Electrostatic Chuck 200

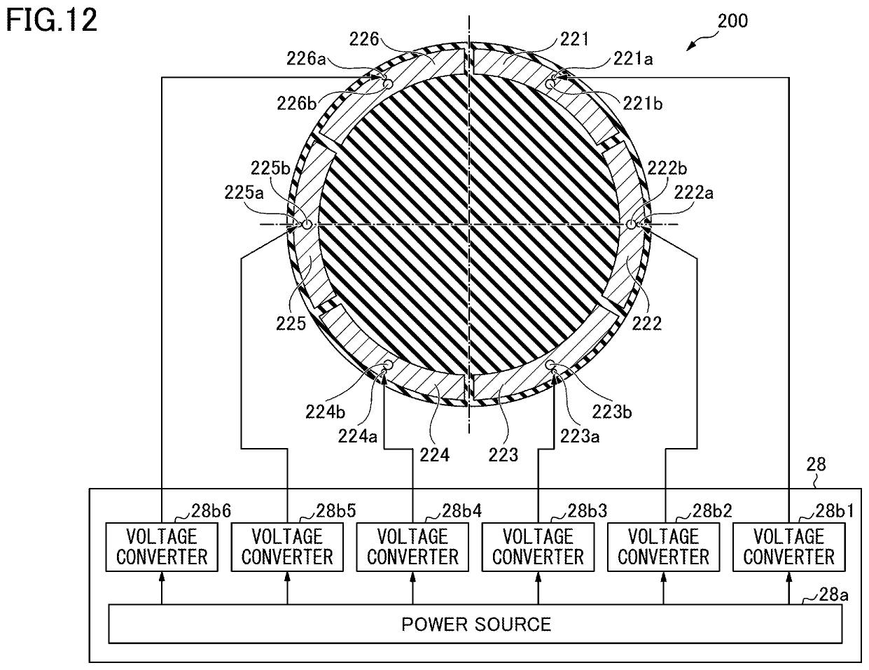

Next, an example of the control method for controlling the substrate support assembly 5 will be described. The power supply to the electrostatic chuck 200 will be described. FIG. 12 is a diagram for explaining the power supply to the electrostatic chuck 200 of the substrate processing apparatus 1 according to this embodiment. The edge ring attraction electrode plates 221 through 226, provided in correspondence with the edge ring pieces 301 through 306, are connected to the DC power supply 28. The DC power supply 28 includes a power source 28a, and voltage converters 28b1 through 28b6 provided in correspondence with the edge ring attraction electrode plates 221 through 226, respectively. An output voltage of each of the voltage converters 28b1 through 28b6, responsive to power supplied from the power source 28a, can be set by the controller 43. Each of the voltage converters 28b1 through 28b6 carries out a control so that the output voltage thereof becomes a set voltage value. The substrate support assembly 5 is controlled by controlling the power supplied to the electrostatic chuck 200.

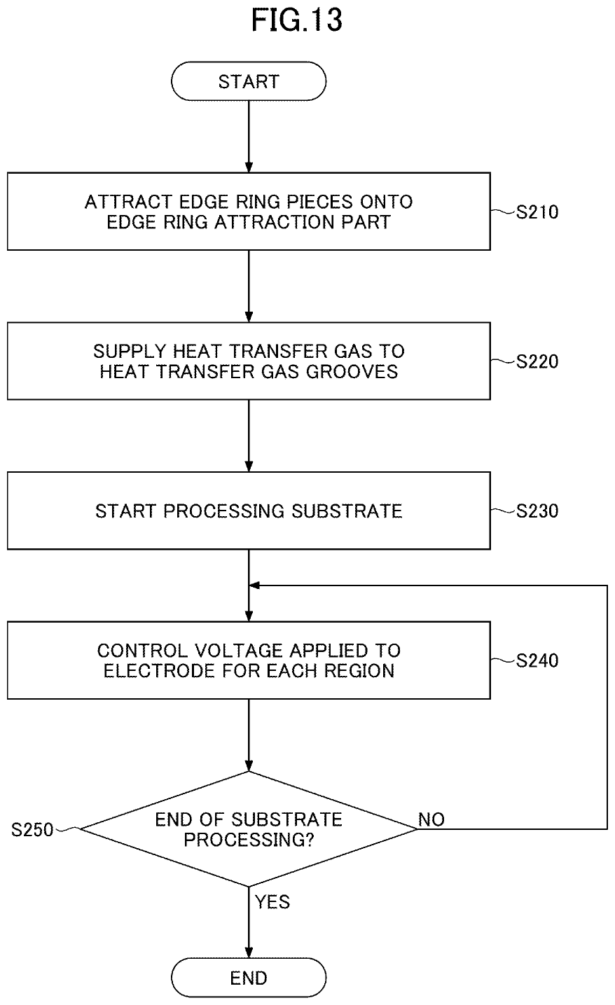

The substrate processing method using the substrate processing apparatus 1 will be described. FIG. 13 is a diagram for explaining the substrate processing method of the substrate processing apparatus 1 according to this embodiment. More particularly, FIG. 13 is a flow chart of the control carried out by the controller 43. Each processing step (process) will now be described.

### Step S210

First, the controller 43 carries out a control so as to attach the plurality of edge ring pieces 301, 302, 303, 304, 305, and 306 onto the edge ring attraction part 200b.

### Step S220

Next, the controller 43 carries out a control to supply the heat transfer gas to the heat transfer gas grooves so as to execute the substrate processing.

### Step S230

Next, the controller 43 starts processing (substrate processing) of the substrate W (wafer). For example, the substrate processing etches the substrate W (wafer).

### Step S240

Next, the controller 43 carries out a control to control the applied voltage for each of the regions, that is, the electrode of each of the edge ring pieces.

### Step S250

Next, the controller 43 determines whether or not the substrate processing ended. If the substrate processing ends and the decision result in step S250 is Yes, the process ends. On the other hand, if the substrate processing has not ended and the decision result in step S250 is No, the process returns to step S240 in order to repeat the process from step S240. The processing of the substrate (substrate processing step) is performed in parallel, between step S230 and step S250.

By performing the process described above, it is possible to control the temperature for each of the edge ring pieces.

For example, the process will be described with reference to FIG. 9. The region RA of the substrate W (wafer) will be described. When increasing the etching rate in the region RA of the substrate W, the voltage supplied to the edge ring attraction electrode plate 226 corresponding to the edge ring piece 306 near the region RA is increased. When the voltage supplied to the edge ring attraction electrode plate 226 corresponding to the edge ring piece 306 is increased, the temperature of the edge ring piece 306 decreases. By decreasing the temperature of the edge ring piece 306, the etching rate in the region RA of the substrate W (wafer) near the edge ring piece 306 can be increased. The description given above is merely an example, and depending on the type of film (film material) on the substrate W, the etching rate may decrease when the temperature of the edge ring piece is decreased. In this case, by increasing the temperature of the edge ring piece, it is possible to increase the etching rate.

Next, the region RB of the substrate W (wafer) will be described. When decreasing the etching rate of the region RB of the substrate W (wafer), the voltage supplied to the edge ring attraction electrode plate 223 corresponding to the edge ring piece 303 near the region RB is decreased. When the voltage supplied to the edge ring attraction electrode plate 223 corresponding to the edge ring piece 306 is decreased, the temperature of the edge ring piece 303 increases. By increasing the temperature of the edge ring piece 303, the etching rate in the region RB of the substrate W (wafer) near the edge ring piece 303 can be decreased. The description given above is merely an example, and depending on the type of film (film material) on the substrate W, the etching rate may increase when the temperature of the edge ring piece is increased. In this case, by decreasing the temperature of the edge ring piece, it is possible to decrease the etching rate.

Accordingly, by forming the edge ring 300 from the plurality of edge ring pieces 301 through 306 segmented in the circumferential direction, and independently controlling the voltages supplied to the electrodes of the plurality of edge ring pieces 301 through 306 for the attraction thereof, it is possible to improve the temperature controllability of the edge ring 300. In other words, the temperature control can be performed for each of the regions corresponding to the plurality of edge ring pieces 301 through 306 segmented in the circumferential direction.

### Setting Heat Transfer Gas Pressure and Power Supply Voltage

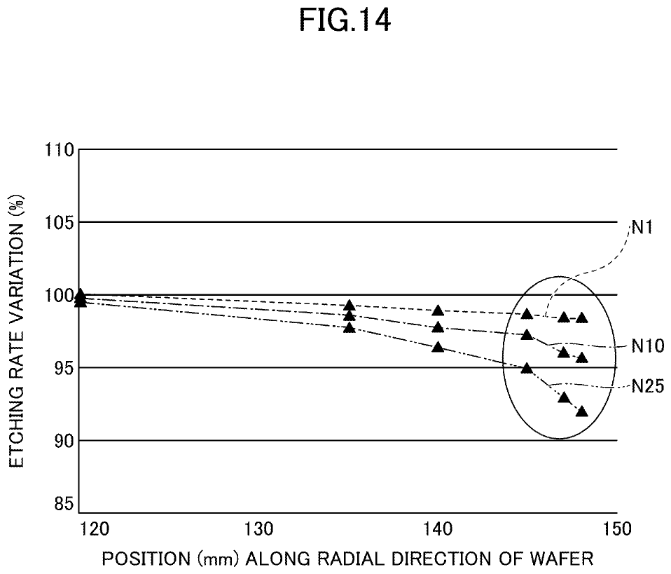

The set values for the pressure of the heat transfer gas and the voltage of the power supply, which are to be set, may be determined according to the number of substrates (wafers) processed by the substrate processing apparatus 1, the lot number, or the like, for example. FIG. 14 is a diagram for explaining a processing number and an etching rate variation in the substrate processing apparatus 1 according to this embodiment. In FIG. 14, the abscissa indicates a position along the radial direction of the wafer to be subjected to the processing, and the ordinate indicates the etching rate variation. A line N1 indicates the etching rate variation when the substrate processing is performed on a single wafer (first wafer). A line N10 indicates the etching rate variation when the substrate processing is performed on ten wafers (tenth wafer). A line N25 indicates the etching rate variation when the substrate processing is performed on twenty-five (twenty-fifth wafer).

As the number of wafers subjected to the substrate processing increases, the etching rate of wafer, particularly in a vicinity of an end or edge of the wafer, decreases. The etching rate of the wafer decreases as the number of wafers subjected to the substrate processing increases, because the temperature of the edge ring increases when the substrate processing is performed. FIG. 14 illustrates the results of testing the etching rate variation when the edge ring is not attracted and a cooling gas is not supplied. Accordingly, the setting of the pressure of the heat transfer gas and the voltage of the power supply may be varied based on data indicating a correlation between the etching rate and the number of wafers subjected to the substrate processing (number of processed wafers). In addition, because the number of wafers subjected to the substrate processing (number of processed wafers) may be regarded as the time for which the substrate is processed, that is, the processing time of the substrate, the etching rate and the processing time of the substrate may be set based on the data indicating the correlation between the etching rate and the processing time of the substrate. Further, the setting of the voltage of the power supply may be varied based on the correlation information (data indicating the correlation) between the temperatures of the edge ring pieces and the set values of the voltage.

The temperature of the edge ring piece may be controlled by combining both the control of the pressure of the heat transfer gas supplied to the edge ring piece, and the control of the voltage supplied to the electrode of the edge ring piece.

### End Structure of Edge Ring Pieces 301 Through 306

Structures of segmenting portions of the edge ring 300, that is, an end structure of the edge ring pieces 301 through 306, will be described. The end structure of the edge ring pieces 301 through 306 between two mutually adjacent edge ring pieces, such as a joint between an end 301b of the edge ring piece 301 and an end 302a of the edge ring piece 302 in FIG. 3, or a joint between an end 301a of the edge ring piece 301 and an end 306b of the edge ring piece 306, for example, is preferably a structure that does not expose the edge ring placing surface 200b1 to the plasma. More particularly, both ends along the circumferential direction of each of the edge ring pieces 301 through 306 preferably have a structure complementary to and overlapping in the vertical direction with respect to a structure of the end of an adjacent one of the edge ring pieces 301 through 306. The end structures of the edge ring piece 301, and the edge ring piece 302 and the edge ring piece 306 which are adjacent to the edge ring piece 301, will be described below. Although the description below is given for specific edge ring pieces, the same applies to the other edge ring pieces.

### FIRST EXAMPLE

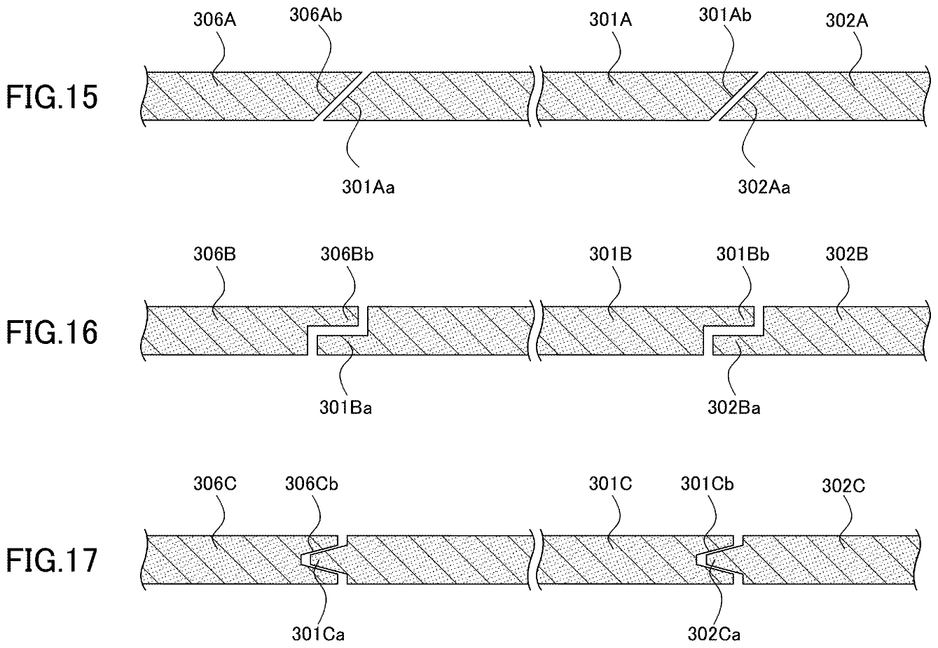

FIG. 15 is a cross sectional view of ends of an edge ring piece 301A of the substrate processing apparatus 1 according to this embodiment, and an edge ring piece 302A and an edge ring piece 306A which are adjacent to the edge ring piece 301A.

In FIG. 15, the left end of each of the edge ring pieces 301A, 302A, and 306A may be regarded as a first end (or one end), and the right end of each of the edge ring pieces 301A, 302A, and 306A may be regarded as a second end (or the other end). The first ends of the edge ring pieces 301A and 302A have first sloping surfaces 301Aa and 302Aa, respectively. In addition, the second ends of the edge ring pieces 301A and 306A have second sloping surfaces 301Ab and 306Ab, respectively. In a state where the edge ring 300 is attracted to the edge ring attraction part 200b, the first sloping surface 301Aa of the edge ring piece 301A makes contact with the second sloping surface 306Ab of the adjacent edge ring piece 306A. Similarly, the second sloping surface 301Ab of the edge ring piece 301A makes contact with the first sloping surface 302Aa of the adjacent edge ring piece 302A. In other words, the first sloping surface 301Aa of the edge ring piece 301A is a complementary sloping surface that overlaps the second sloping surface 306Ab of the adjacent edge ring piece 306A along the vertical direction. Further, the second sloping surface 301Ab of the edge ring piece 301A is a complementary sloping surface that overlaps the first sloping surface 302Aa of the adjacent edge ring piece 302A along the vertical direction. Hence, according to this first example, it is possible to avoid exposure of the edge ring placing surface 200b1 to the plasma at the joints between the edge ring piece 301A and the adjacent edge ring pieces 302A and 306A, respectively.

### SECOND EXAMPLE

FIG. 16 is a cross sectional view of ends of an edge ring piece 301B of the substrate processing apparatus 1 according to this embodiment, and an edge ring piece 302B and an edge ring piece 306B which are adjacent to the edge ring piece 301B.

In FIG. 16, the left end of each of the edge ring pieces 301B, 302B, and 306B may be regarded as a first end (or one end), and the right end of each of the edge ring pieces 301B, 302B, and 306B may be regarded as a second end (or the other end). The first ends of the edge ring pieces 301B and 302B have first stepped portions 301Ba and 302Ba, respectively. In addition, the second ends of the edge ring pieces 301B and 306B have second stepped portions 301Bb and 306Bb, respectively. In a state where the edge ring 300 is attracted to the edge ring attraction part 200b, the first stepped portion 301Ba of the edge ring piece 301B fits onto the second stepped portion 306Bb of the adjacent edge ring piece 306B. Similarly, the second stepped portion 301Bb of the edge ring piece 301B fits onto the first stepped portion 302Ba of the adjacent edge ring piece 302B. In other words, the first stepped portion 301Ba of the edge ring piece 301B is a complementary stepped portion that overlaps the second stepped portion 306Bb of the adjacent edge ring piece 306B along the vertical direction. Further, the second stepped portion 301Bb of the edge ring piece 301B is a complementary stepped portion that overlaps the first stepped portion 302Ba of the adjacent edge ring piece 302B along the vertical direction. Hence, according to this second example, it is possible to avoid exposure of the edge ring placing surface 200b1 to the plasma at the joints between the edge ring piece 301B and the adjacent edge ring pieces 302B and 306B, respectively.

### THIRD EXAMPLE

FIG. 17 is a cross sectional view of ends of an edge ring piece 301C of the substrate processing apparatus 1 according to this embodiment, and an edge ring piece 302C and an edge ring piece 306C which are adjacent to the edge ring piece 301C.

In FIG. 17, the left end of each of the edge ring pieces 301C, 302C, and 306C may be regarded as a first end (or one end), and the right end of each of the edge ring pieces 301C, 302C, and 306C may be regarded as a second end (or the other end). The first ends of the edge ring pieces 301C and 302C have projections 301Ca and 302Ca, respectively. In addition, the second ends of the edge ring pieces 301C and 306C have recesses 301Cb and 306Cb, respectively. In a state where the edge ring 300 is attracted to the edge ring attraction part 200b, the projection 301Ca of the edge ring piece 301C fits into the recess 306Cb of the adjacent edge ring piece 306C. Similarly, the recess 301Cb of the edge ring piece 301C fits over the projection 302Ca of the adjacent edge ring piece 302C. In other words, the projection 301Ca of the edge ring piece 301C is a complementary projection that overlaps the recess 306Cb of the adjacent edge ring piece 306C along the vertical direction. Further, the recess 301Cb of the edge ring piece 301C is a complementary recess that overlaps the projection 302Ca of the adjacent edge ring piece 302C along the vertical direction. Hence, according to this third example, it is possible to avoid exposure of the edge ring placing surface 200b1 to the plasma at the joints between the edge ring piece 301C and the adjacent edge ring pieces 302C and 306C, respectively.

With regard to the examples of the ends of the edge ring described above, the same examples may be used in the substrate support assembly 5, or a combination of the examples may be used.

### Advantageous Features

In the related art, the edge ring is integrally molded, and due to the accuracy of finishing, there is a certain difference between the flatness of the edge ring placing surface of the electrostatic chuck, and the flatness of the back surface of the edge ring. In addition, because the edge ring is thick compared to the substrate W, it is difficult to deform the edge ring according to the surface profile or shape of the edge ring placing surface, even if the edge ring is attracted onto the electrostatic chuck. Particularly during the substrate processing, if the flatness of the edge ring placing surface changes due to a temperature change of the electrostatic chuck, it is difficult for the edge ring to follow the change in the surface profile or shape of the edge ring placing surface. For this reason, in the edge ring that is integrally molded, it is difficult to reduce the leak of heat transfer gas between the edge ring and the electrostatic chuck.

In contrast, in the substrate support assembly 5 according to this embodiment, the edge ring 300 is famed of the plurality of edge ring pieces 301 through 306. For this reason, even if there is a difference between the flatness of the edge ring placing surface 200b1 of the electrostatic chuck 200 and the flatness of the back surface of the edge ring 300 (edge ring pieces 301 through 306), the edge ring 300 can be placed according to the surface profile or shape of the edge ring placing surface 200b1. In addition, even if the flatness of the edge ring placing surface 200b1 changes due to the temperature change of the electrostatic chuck 200 during the substrate processing, the edge ring 300 can follow the change in the surface profile or shape of the edge ring placing surface 200b1. Hence, in the substrate support assembly 5 according to this embodiment, it is possible to effectively reduce the leak of the heat transfer gas. As a result, because the pressure of the heat transfer gas can be maintained constant during the substrate processing, the efficiency of the heat transfer between the edge ring 300 and the electrostatic chuck 200 can be improved.

Moreover, the substrate support assembly 5 according to this embodiment includes the heat transfer gas grooves 231 through 236 for each of the regions where the plurality of edge ring pieces 301 through 306 are placed. Accordingly, the amount of heat transfer gas supplied to each of the heat transfer gas grooves 231 through 236 can be controlled independently, thereby enabling the temperature to be controlled for each of the edge ring pieces 301 through 306.

Furthermore, the substrate support assembly 5 according to this embodiment includes the edge ring attraction electrode plates 221 through 226 for each of the regions where the plurality of edge ring pieces 301 through 306 are placed. Hence, the attraction force with respect to each of the edge ring pieces 301 through 306 can be controlled independently, thereby enabling the temperature distribution to be controlled for each of the edge ring pieces 301 through 306.

The substrate processing apparatus according to the embodiments of the present disclosure should be considered exemplary in all respects and non-limiting. Various variations, modifications, and substitutions may be made in the embodiments described above, without departing from the scope and spirit of the present disclosure. The elements described in the embodiments may have other configurations to an extent not contradictory thereto, and may be combined, as appropriate, to an extent not contradictory thereto.

The substrate processing apparatus of the present disclosure is applicable to various types of apparatuses which generate Capacity Coupled Plasma (CCP), Inducibly Coupled Plasma (ICP), and microwave generated plasma, such as Radial Line Slot Antenna (RLSA) generated plasma, Electron Cyclotron Resonance Plasma (ECR), Helicon Wave Plasma (HWP), or the like, for example.

Therefore, according to the embodiments of the present disclosure, it is possible to provide a technique for reducing the leak of the heat transfer gas during the edge ring attraction.

While certain embodiments have been described, these embodiments have been presented by way of example only, and are not intended to limit the scope of the disclosure. Indeed, the embodiments described herein may be embodied in a variety of other forms. Furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A substrate support assembly on which a substrate is placed, the substrate support assembly comprising:
a base;
an electrostatic chuck disposed on the base; and
an edge ring disposed in a periphery of the substrate,
wherein the edge ring is formed of a plurality of edge ring pieces that are segmented in a circumferential direction,
wherein the electrostatic chuck includes a substrate attraction part configured to attract the substrate, and an edge ring attraction part configured to attract the plurality of edge ring pieces, and
wherein the edge ring attraction part includes a plurality of heat transfer gas grooves, supplied with a heat transfer gas, in a plurality of regions where the plurality of edge ring pieces are attracted, respectively.

2. The substrate support assembly as claimed in claim 1, wherein each of the plurality of heat transfer gas grooves includes a heat transfer gas supply hole.

3. The substrate support assembly as claimed in claim 1, wherein the edge ring attraction part includes a plurality of electrodes for attracting the plurality of edge ring pieces in the plurality of regions, respectively.

4. The substrate support assembly as claimed in claim 1, wherein both ends along the circumferential direction of each of the plurality of edge ring pieces have a structure complementary to and overlapping in a vertical direction with respect to a structure of an end of an adjacent one of the plurality of edge ring pieces.

5. The substrate support assembly as claimed in claim 4, wherein each of the plurality of edge ring pieces has a first sloping surface at one end thereof, and a second sloping surface at the other end thereof and making contact with a first sloping surface of an adjacent one of the plurality of edge ring pieces.

6. The substrate support assembly as claimed in claim 4, wherein each of the plurality of edge ring pieces has a first stepped portion at one end thereof, and a second stepped portion at the other end thereof and fitting to a first step portion of an adjacent one of the plurality of edge ring pieces.

7. The substrate support assembly as claimed in claim 4, wherein each of the plurality of edge ring pieces has a recess at one end thereof, and a projection at the other end thereof and fitted into a recess of an adjacent one of the plurality of edge ring pieces.

8. The substrate support assembly as claimed in claim 1, wherein the edge ring is formed of three to nine edge ring pieces.

9. A substrate processing apparatus comprising:
the substrate support assembly according to claim 1;
a processing chamber including the substrate support assembly disposed therein; and
a controller configured to control the substrate processing apparatus.

10. The substrate processing apparatus as claimed in claim 9, further comprising:
a temperature sensor configured to measure a temperature of each of the plurality of edge ring pieces.

11. A substrate processing method which uses a substrate processing apparatus,
the substrate processing apparatus including
a processing chamber,
a substrate support assembly disposed inside the processing chamber, and
a controller configured to control the substrate processing apparatus,
the substrate support assembly including
a base,
an electrostatic chuck disposed on the base, and
an edge ring disposed in a periphery of the substrate,
wherein the edge ring is formed of a plurality of edge ring pieces that are segmented in a circumferential direction,
wherein the electrostatic chuck includes a substrate attraction part configured to attract the substrate, and an edge ring attraction part configured to attract the plurality of edge ring pieces, and
wherein the edge ring attraction part includes a plurality of heat transfer gas grooves, supplied with a heat transfer gas, in a plurality of regions where the plurality of edge ring pieces are attracted, respectively,
the substrate processing method comprising:
attracting the plurality of edge ring pieces onto the edge ring attraction part;
supplying the heat transfer gas to the plurality of heat transfer gas grooves;
processing the substrate; and
controlling a pressure of the heat transfer gas for each of the plurality of regions.

12. The substrate processing method as claimed in claim 11, wherein the controlling controls the pressure of the heat transfer gas for each of the plurality of regions, based on data indicating a correlation between an etching rate, and a processing time of the substrate or a number of substrates processed.

13. The substrate processing method as claimed in claim 11, wherein the controlling includes
measuring a temperature of each of the plurality of edge ring pieces by a temperature sensor of the substrate processing apparatus, and
controlling the pressure of the heat transfer gas for each of the plurality of regions, based on data indicating a correlation between temperatures of the plurality of edge ring pieces and pressures of the heat transfer gas supplied to the plurality of heat transfer gas groove, and the temperature of each of the plurality of edge rings measured by the measuring.

14. A substrate processing method which uses a substrate processing apparatus,
the substrate processing apparatus including
a processing chamber,
a substrate support assembly disposed inside the processing chamber, and
a controller configured to control the substrate processing apparatus,
the substrate support assembly including
a base,
an electrostatic chuck disposed on the base, and
an edge ring disposed in a periphery of the substrate,
wherein the edge ring is formed of a plurality of edge ring pieces that are segmented in a circumferential direction,
wherein the electrostatic chuck includes a substrate attraction part configured to attract the substrate, and an edge ring attraction part configured to attract the plurality of edge ring pieces, and
wherein the edge ring attraction part includes a plurality of heat transfer gas grooves supplied with a heat transfer gas, and a plurality of electrodes for attracting the plurality of edge ring pieces, in a plurality of regions where the plurality of edge ring pieces are attracted, respectively,
the substrate processing method comprising:
attracting the plurality of edge ring pieces onto the edge ring attraction part;
supplying the heat transfer gas to the plurality of heat transfer gas grooves;
processing the substrate; and
controlling voltages applied to the plurality of electrodes for each of the plurality of regions.

15. The substrate processing method as claimed in claim 14, wherein the controlling controls the voltages applied to the plurality of electrodes for each of the plurality of regions, based on data indicating a correlation between an etching rate, and a processing time of the substrate or a number of substrates processed.

16. The substrate processing method as claimed in claim 14, wherein the controlling includes
measuring a temperature of each of the plurality of edge ring pieces by a temperature sensor of the substrate processing apparatus, and
controlling the voltages applied to the plurality of electrodes for each of the plurality of regions, based on data indicating a correlation between temperatures of the plurality of edge ring pieces and voltages applied to the plurality of electrodes, and the temperature of the plurality of edge rings measured by the measuring.

17. The substrate processing method as claimed in claim 14, wherein the controlling further includes
controlling a pressure of the heat transfer gas for each of the plurality of regions.
